(19) United States
(12) Patent Application Publication
(10) Pub. No.: US 2005/0274498 A1
(43) Pub. Date: Dec. 15, 2005

(54) Heat dissipation assembly with air guide device

(75) Inventors: Dong-Yun Li, Shenzhen (CN); Min Li, Shenzhen (CN); Hong-Bo Shi, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: Foxconn Technology Co., Ltd., Tu-Cheng City (TW)

(21) Appl. No.: 11/137,178

(22) Filed: May 25, 2005

(30) Foreign Application Priority Data
Jun. 11, 2004 (CN) 200420047059.8

(51) Int. Cl. H05K 7/20

(52) U.S. Cl. 165/121; 361/697

(57) ABSTRACT

A heat dissipation assembly includes a heat sink, a fan attached to the heat sink, for providing forced airflow to the heat sink; and an air guide device, adapted for leading air between the fan and an air exchange port. The air guide device includes an immovable duct, having one end attached to the fan, a movable duct, connecting to the immovable duct and capable of moving relative to the immovable duct, and spring members arranged between the immovable duct and the movable duct to impel the movable duct relative to the immovable duct, such that a height of the air guide device is adjustable expediently.

### BACKGROUND

1. Field

This invention is related to heat dissipation assemblies, and particularly to a heat dissipation assembly incorporating an air guide device.

2. Prior Art

During operation of a computer, electronic devices such as central processing units (CPUs) frequently generate large amounts of heat, therefore a heat dissipation assembly is desired to dissipate heat from the electronic device. Generally, the heat dissipation assembly comprises a heat sink and a fan. The heat sink is attached to a CPU with a bottom surface thereof contacting an outer surface of the CPU, while with a top surface forming thereon a plurality of spaced fins which define a plurality of channels therebetween. The fan is installed at a side of the fins for providing forced airflow through the channels to accelerate heat convection. However, heated air often can not freely flow out of a computer enclosure of the computer. Hence, a large amounts of heated air accumulates within the computer enclosure. What is the worst is the heated airflow often refluence to the CPU. As a result, heat dissipating efficiency of the heat dissipation assembly is low.

In order to prevent the heated airflow from refluencing to the CPU, an air guide device is added to the heat dissipation assembly to lead air in or out of the computer. The air guide device conventionally is a cylindrical duct. One end of the cylindrical duct hoods an upper portion of the fan, while an opposite end thereof is attached to a computer enclosure. A plurality of air apertures, corresponding to the duct, is defined in the computer enclosure to exchange heat with an ambient outside of the computer. In operation, via the air guide device, outside cooling air blows to the heat sink or heated air from the heat sink flows away from the computer enclosure, thereby preventing heated airflow from refluencing to the CPU. However, a height of the air guide device is constant and only fits a kind of special computer enclosures whose height or inner space is fixed. There are so many kinds of computer enclosures which have different height or inner air space. Therefore, the air guide device setout above with a constant height, can not meet with the different computers.

Therefore, a heat dissipation assembly with an air guide device height of which is adjustable, is applied. FIG. 6 illustrates an air guide device according to a conventional invention, the air guide device comprises a hood 100 and a duct 200 connecting the hood 100 with a computer enclosure (not shown). The duct 200 has a cover portion 202 extending from an end thereof, for being attached to the computer enclosure, and a plurality of annular grooves 204 defined in an outer circumferential surface of an opposite end thereof. The hood 100 has one end covering a fan (not shown), and an opposite end forming a connecting portion. The connecting portion forms a plurality of protrusions 102 on an inner surface thereof, for adjustable connecting to the duct 200. In assembly, the protrusions 102 are engaged in selected annular grooves 204, to retain the hood 100 on the duct 200 at a desired position. However, in order to connect the duct 200 to the hood 100 perfectly, the protrusions 102 must contact the annular grooves 204 intensively. Consequently, it is hard to move the protrusions 102 into the annular grooves 204 at a desired position. Moreover, there is a distance between the adjacent annular grooves 204, so that, the height adjusted is not accurate.

### SUMMARY

Accordingly, what is needed is to provide a heat dissipation assembly with a air guide device a height of which is adjustable expediently in order to adapt to computer enclosures with different heights or inner air space.

A heat dissipation assembly comprises a heat sink, a fan attached to the heat sink, for providing forced airflow to the heat sink; and an air guide device, adapted for leading air between the fan and an air exchange port. The air guide device comprises an immovable duct, having one end attached to the fan, a movable duct, connecting to the immovable duct and capable of moving relative to the immovable duct, and spring members arranged between the immovable duct and the movable duct to impel the movable duct relative to the immovable duct, such that a height of the air guide device is adjustable expediently.

Other advantages and novel features of the present invention will be drawn from the following detailed description of preferred embodiments of the present invention with the attached drawings, in which:

### BRIEF DESCRIPTION OF THE DRAWINGS

FIG. 1 is an exploded view of a heat dissipation assembly with a air guide device in accordance with a preferred embodiment of the present invention;

FIG. 2 is an assembly view of FIG. 1;

FIG. 3 is sectional view of FIG. 1, taken along line III-III of FIG. 2;

FIG. 4 is similar to FIG. 3, but show a height of the air guide device being adjusted.

FIG. 5 is an exploded view of a air guide device in accordance with an alternative embodiment of the present invention; and

FIG. 6 is an exploded view of a air guide device in accordance with a conventional invention.

### DETAILED DESCRIPTION OF THE EMBODIMENTS

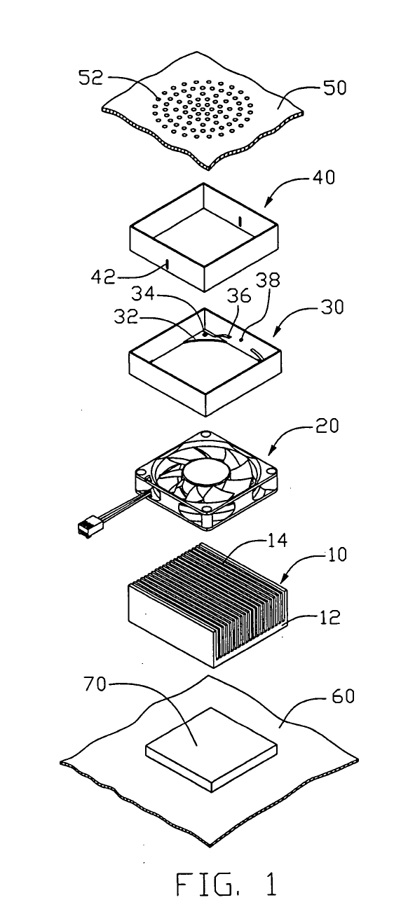

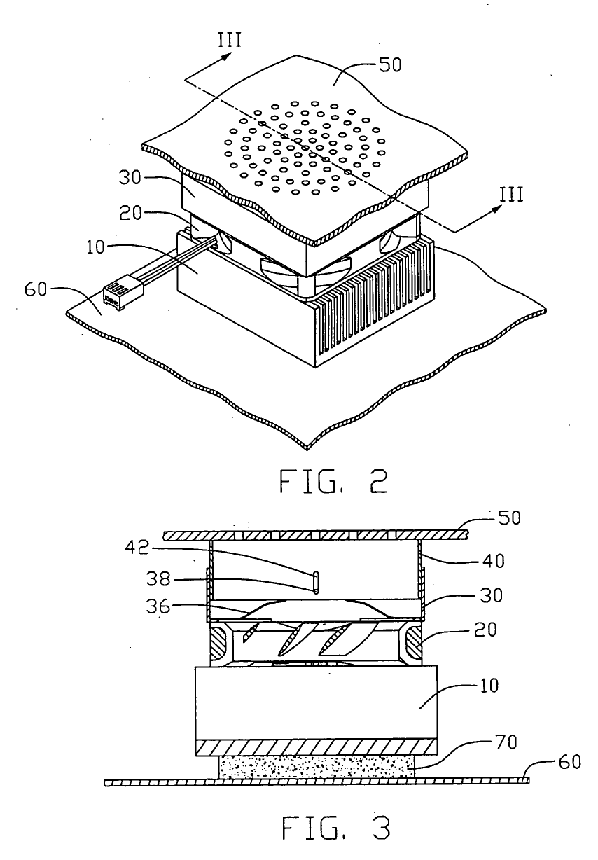

Referring to FIG. 1, a heat dissipation assembly comprises an air guide device, a fan 20 forming an airflow source, and a heat sink 10. The heat sink 10 comprises a base 12 and a plurality of fins 14 arranged on an upper surface thereof. A bottom surface of the base 12 is adapted for attaching to an outer surface of a CPU 70 amounted on a circuit board 60.

The air guide device comprises an rectangular immovable duct 30 and a movable duct 40 adjustable connecting to the immovable duct 30. A board 32 with a hole 34 defined therein, is formed at each corner of a bottom of the immovable duct 30, for securing the immovable duct 30 to the fan 20 so as to provide an inlet for airflow of the fan 20 into the air guide device. A spring member, such as a spring tab 36, approaching to an inner sidewall of the immovable duct 30, extends from each board 32 and tilts to the movable duct 40, for flexibly impelling the movable duct 40. Also, the spring tab 36 can be replaced by a spring attached to the board 32. Two face-to-face horizontal protrusions 38 extend from two opposite inner sidewalls of the immovable duct 30 respectively. Understandably, amount of the protrusion 38 is not limited, it can be one, two, three, four and so on.

The movable duct 40 is rectangular and a size of which is appreciably smaller than that of the immovable duct 30, such that the movable duct 40 can slide into the immovable duct 30 along sidewalls thereof. Two longitudinal slots 42 are defined in two opposite sidewalls of the movable duct 40 respectively, for the protrusions 38 of the immovable duct 30 capable of slidable engaging therein and determining an adjustable range of the air guide device. Understandably, amount of the slot 42 is corresponding to that of the protrusion 38. The movable duct 40 has an end adapted for being attached to an air exchange port used as an airflow exit, such as a computer enclosure 50. The computer enclosure 50 defines a plurality of openings 52 corresponding to the end of the movable duct 40, for exchanging air between the movable duct 40 and an ambient out of the computer enclosure 50.

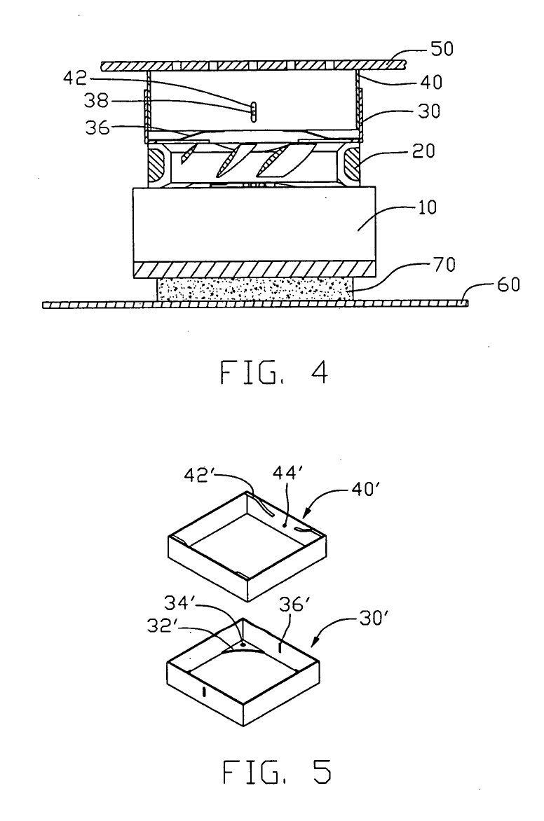

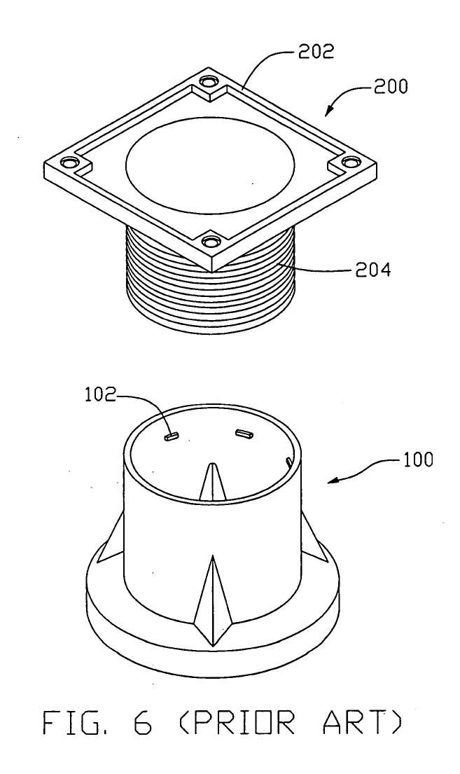

Referring also to FIG. 1˜FIG. 4, in assembly, the fan 20 and the immovable duct 30 are secured to the heat sink 10 via fasteners matching with the holes 34. The movable duct 40 slides into the immovable duct 30, with the slots 42 engaging the protrusions 38 of the immovable duct 30 therein. Meanwhile, the spring tabs 36 of the immovable duct 30 flexibly abut against an edge of the movable duct 40, such that the movable duct 40 was impelled to move upwardly automatically relative to the immovable duct 30, with the protrusions 38 of the immovable duct 30 sliding in the slots 42, until the end of the movable duct 40 touches the computer enclosure 50. Then, the end of the movable duct 40 is attached to the computer enclosure 50.

According to the preferred embodiment of the present invention, as a replacement, the at least one protrusion 38 extends from at least one outer sidewall of the immovable duct 30. Correspondingly, a size of the movable duct 40 is appreciably larger than that of the immovable duct 30, such that the movable duct 40 can slide outside the immovable duct 30 along sidewalls thereof. And the spring tabs 36 are varied correspondingly to impel the movable duct 40.

Referring to FIG. 5, an air guide device according to an alternative embodiment of the present invention is shown. The air guide device is substantial similar to the preferred embodiment. However, an immovable duct 30′ defines at least one longitudinal slot 36′ in at least one sidewall thereof respectively. A movable duct 40′ forms four spring tabs 42′ from two opposite inner sidewalls thereof. Each spring tab 42′ tilts to the immovable duct 30′ to impel it, such that the movable duct 40′ moves upwardly under an opposite acting force of the spring tabs 42′. At least one horizontal protrusion 44′ corresponding to the at least one slot 36′ extends from at least one inner sidewall of the movable duct 40′.

According to the alternative embodiment of the present invention, as a replacement, the at least one protrusion 44′ extends from at least one outer sidewall of the movable duct 40′. Correspondingly, a size of the movable duct 40′ is appreciably smaller than that of the immovable duct 30′, such that the movable duct 40′ can slide into the immovable duct 30′ along sidewalls thereof. And the spring tabs 42′ are varied correspondingly to impel the immovable duct 30′.

According to the embodiment set out above, the movable duct 40/40′ capable of moving relative to the immovable duct 30/30′, via the spring tabs 36/42′ flexibly impelling the movable duct 40, immovable duct 30′, and the protrusions 38/44′ sliding in the slots 42/36′ automatically. Thus, the air guide device is adjustable expediently to adapt to computer enclosures with different height.

It is to be understood, however, that even though numerous characteristics and advantages of the present invention have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

1. An air guide device comprising:
an immovable duct; and
a movable duct, connecting to the immovable duct and capable of moving relative to the immovable duct;
wherein, spring members are arranged between the immovable duct and the movable duct to move the movable duct relative to the immovable duct, such that a height of the air guide device is adjustable.

2. The air guide device of claim 1, wherein the spring members are formed from the immovable duct, and tilt to the movable duct.

3. The air guide device of claim 1, wherein the spring members are formed from the movable duct, and tilt to the immovable duct.

4. The air guide device of claim 1, wherein at least one pair of slot and protrusion slidable in the slot is arranged between the immovable duct and the movable duct to determine an adjustable range of the air guide device.

5. The air guide device of claim 4, wherein the at least one protrusion extends from at least one sidewall of the immovable duct, and wherein the at least one slot is longitudinally defined in at least one sidewall of the movable duct.

6. The air guide device of claim 4, wherein the at least one protrusion extends from at least one sidewall of the movable duct, and wherein the at least one slot is longitudinally defined in at least one sidewall of the immovable duct.

7. The air guide device of claim 1, wherein the movable duct is slidable into the immovable duct.

8. The air guide device of claim 1, wherein the movable duct is slidable outside the immovable duct.

9. The air guide device of claim 1, wherein the spring members are at least two spring tabs.

10. A heat dissipation assembly, comprising:
a heat sink;
a fan attached to the heat sink, for providing forced airflow to the heat sink; and
an air guide device, adapted for leading air between the fan and an air exchange port, the air guide device comprising:
an immovable duct, having one end attached to the fan;
a movable duct, connecting to the immovable duct and capable of moving relative to the immovable duct; and
spring members arranged between the immovable duct and the movable duct to impel the movable duct relative to the immovable duct, such that a height of the air guide device is adjustable.

11. The heat dissipation assembly claim 10, wherein at least one pair of slot and protrusion slidable in the slot is arranged between the immovable duct and the movable duct to determine an adjustable range of the air guide device.

12. The heat dissipation assembly claim 10, wherein the immovable duct forms a board at each bottom corner thereof, and the board is attached to the fan via a fastener matching with a hole defined on the board.

13. The heat dissipation assembly of claim 12, wherein the spring members extend from the boards, tilt to the movable duct and abut against the movable duct.

14. The heat dissipation assembly of claim 10, wherein the spring members extend from a sidewall of the movable duct, tilt to the immovable duct and abut against immovable duct.

15. The heat dissipation assembly of claim 10, wherein the movable duct is slidable into the immovable duct.

16. The heat dissipation assembly of claim 10, wherein the movable duct is slidable outside the immovable duct.

17. The heat dissipation assembly of claim 10, wherein the air exchange port is a computer enclosure with a plurality of openings defined therein.

18. An air guide device comprising:
an immovable duct disposed next to an airflow source so as to provide an inlet for airflow therefrom; and
a movable duct movably engagable with said immovable duct and reachable to an exit of said airflow, said movable duct being resiliently movable relative to said immovable duct along a direction of being away from said immovable duct so as to reach said exit of said airflow.

19. The air guide device of claim 18, wherein at least one spring member is engagable with said immovable duct and said movable duct respectively so as to urge resilient movement of said movable duct relative to said immovable duct along said direction.
